(19) United States
(12) Patent Application Publication
(10) Pub. No.: US 2005/0130077 A1
(43) Pub. Date: Jun. 16, 2005

(54) Method for positioning and transferring at least two different patterns from a supply strip

(75) Inventor: Ulrich Grutter, Walzenhausen (CH)

Correspondence Address: OSTROLENK FABER GERB & SOFFEN, 1180 AVENUE OF THE AMERICAS, NEW YORK, NY, 100368403, US

(73) Assignee: BOBST S.A.

(21) Appl. No.: 10/987,699

(22) Filed: Nov. 12, 2004

(30) Foreign Application Priority Data
Nov. 13, 2003 (CH) 01951/03

(51) Int. Cl. G03F 7/00

(52) U.S. Cl. 430/322; 430/30

(57) ABSTRACT

A method wherein a supply strip (bm) is entrained at a constant speed, which speed is the same as that of the substrate in strip form (c), during transfer between strips of each pattern and according to a speed profile which is determined between two transfers of the patterns. There is determination of the speed profile by measuring the time which elapses between the passages of two homologous references (m1) of two successive groups of areas specific to the patterns to be deposited. From this time there are deduced the times of displacements of the supply strip (bm) during the transfers of the two patterns, calculation of the length between the respective adjacent patterns (Hᵢ, Fᵢ, Gᵢ) on the supply strip (bm), and that length is compared with the length of the displacement between the respective locations of the two same successive patterns on the substrate (c), in order to make the transfer of the said patterns coincide with their respective locations on the said substrate (c).

### BACKGROUND OF THE INVENTION

The present invention relates to a method for positioning and transferring at least two different patterns cut from a supply strip which has a succession of at least two specific areas, with one area for each of the said patterns, onto a substrate in strip form which is entrained at a constant speed, wherein the supply strip is entrained at a constant speed which is the same as the speed of the substrate in strip form during the transfer of each of the patterns, and according to a speed profile which is determined between two transfers of the said patterns.

In presses used to transfer patterns onto a substrate in strip form, particularly a metallized strip, each strip is able to transfer only one pattern. Because it is impossible to have several strips on the same trajectory or path, it is then possible to deposit only a single pattern on this trajectory.

EP 441 596 has proposed a device for transferring, from a support strip for a material to be deposited, images added from this material in predetermined locations of a substrate in strip form, which is entrained at a constant speed. In a device of this type, it is apparent that the length of the material deposited consumed constitutes only a fraction of that of the substrate in strip form. However, the support strip for the material to be deposited is formed by a laminate of high cost. This is why means for displacement were proposed, comprising means for inversion of the longitudinal displacement of the support strip for the material to be deposited. These means for displacement in the reverse direction are disposed respectively upstream and downstream from the means which are used for transfer of the image from the support strip to the substrate in strip form. This reduces the space on the support strip which separates two successive images, in order to economize as far as possible on the consumption of the support strip.

This device makes it possible to economize on the supply strip, but the control process over the strip does not make it possible to position and transfer groups of different patterns from a single supply strip, particularly groups of patterns comprising at least one hologram per group.

### SUMMARY OF THE INVENTION

The object of the present invention is to provide a solution to the above described problem.

For this purpose, the object of this invention is a method wherein a supply strip (bm) is entrained at a constant speed, which speed is the same as that of the substrate in strip form (c), during transfer between strips of each pattern and according to a speed profile which is determined between two transfers of the patterns. There is determination of the speed profile by measuring the time which elapses between the passages of two homologous references (m1) of two successive groups of areas specific to the patterns to be deposited. From this time there are deduced the times of displacements of the supply strip (bm) during the transfers of the two patterns, calculation of the length between the respective adjacent patterns (Hᵢ, Fᵢ, Gᵢ) on the supply strip (bm), and that length is compared with the length of the displacement between the respective locations of the two same successive patterns on the substrate (c), in order to make the transfer of the said patterns coincide with their respective locations on the said substrate (c).

This method makes it possible to deposit different patterns which are situated on the substrate on the trajectory or path of a single supply strip. This would previously have required several strips on a single trajectory, and was consequently obviously impossible to carry out. Above all, it becomes possible to transfer holograms with required accuracy, since this method now not only permits accurate positioning of the transfer tool relative to the imprint on the substrate, but also accurate positioning of the hologram relative to the block for transfer of this hologram onto the substrate.

Consequently, the method according to the invention enables previously unknown possibilities in the field of transfer of patterns onto a substrate in strip form. Consequently, it is possible to transfer at least one hologram with the required accuracy, onto a group comprising at least two different successive patterns transferred. For example, in addition to several holograms, using the same strip, it is possible to transfer one or more standard metallized patterns with different colors, or patterns which produce diffraction of light. It is sufficient to have a supply strip which has as many successive specific areas as there are patterns in a group of patterns, wherein the successive groups each have the same succession of specific areas. The lengths of these areas, other than that/those of the hologram, can be selected in order to cover a certain range of lengths of patterns, such that a single supply strip can be used in order to carry out transfer of different patterns.

Consequently, the user will need substantially to select the hybrid supply strip according to the number of patterns to be transferred by means of this strip. There will therefore be substantially strips which have 2, 3 or 4 specific areas, or more. If a hologram must be transferred, it will be formed before the transfer is carried out onto one of the specific areas. The method according to the invention then makes it possible to obtain accurate positioning of the hologram, in relation both to the transfer tool and to the location of the substrate onto which it must be deposited. The method according to the invention has the greatest advantage in the transfer of a hologram. Transfer of the other patterns requires accurate positioning only of the transfer tool relative to the substrate, in that this pattern must be positioned relative to a previously produced imprint. In relation to the supply strip, it is only necessary for the tool to cut the pattern to be transferred in the specific area. But, since this area is in general longer than the pattern, accuracy relative to this area does not have the same importance as for the hologram.

Other features and advantages of the present invention will become apparent from the following description of the invention which refers to the accompanying drawings.

### BRIEF DESCRIPTION OF THE DRAWINGS

The attached drawing illustrates schematically, and by way of example, an embodiment of implementation of the method which is the subject of the present invention.

FIG. 1 is an explanatory drawing of the implementation; and

FIG. 2 is a diagram of the respective displacements of the substrate in strip form and of the supply strip, on a time basis.

### DESCRIPTION OF PREFERRED EMBODIMENTS

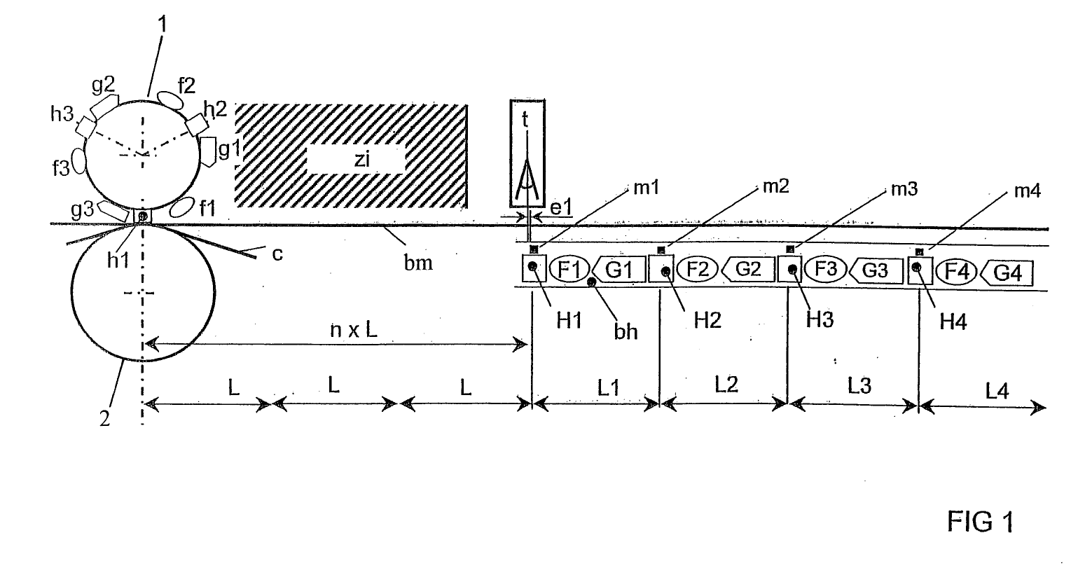

Reference is made substantially to the diagram in FIG. 1 for explanation of the method according to the present invention. The drawing shows a rotary press comprising a block-holder roller 1, which in this example supports three groups of three blocks each, h1, f1, g1; h2, f2, g2; h3, B, g3. The blocks h1, h2, h3 are identical to each other, and the same applies to the blocks f1, f2, B and to the blocks g1, g2, g3. Thus, all the groups of three blocks comprise respective identical blocks. The spaces between successive blocks in each group are also identical, such that homologous groups are involved.

A support roller or counter-roller 2 is situated opposite the roller 1. Two strips bm and c pass between the rollers 1 and 2. The strip c constitutes the substrate onto which the patterns cut by the blocks hᵢ, fᵢ, gᵢ from the supply strip bm, are transferred. The strip bm generally is comprised of a metallized strip. The substrate strip c may be comprised of a strip of cardboard, and in particular cardboard which is designed to form box inserts, after the strip c is later divided into separate sheets or leaves. During its use in the method according to the invention, the strip of cardboard c has already undergone various operations, of which the main one is printing thereon.

The patterns which are later transferred onto this substrate must therefore be positioned accurately relative to the previous printing on the substrate. The adjustment of the position of the blocks on the substrate is obtained by adjusting the angular position of a block on the roller 1, relative to the imprint borne by the substrate c. This operation is conventional, and does not form part of the method according to the present invention, but constitutes an operation of adjustment prior to any transfer of patterns onto a substrate which bears an imprint.

The diagram in FIG. 1 shows four groups of three specific areas, each of which corresponds to one of the patterns to be transferred. The areas H1, F1, G1; H2, F2, G2; H3, F3, G3; H4, F4, G4 are represented with different forms, and the homologous areas in each group have the same forms. This has been done in order to facilitate the explanation, but in reality these areas will be constituted by shorter or longer rectangles, possibly with the same width as the supply strip.

In the example described, it is assumed that the areas Hᵢ (ᵢ being any of 1, 2, etc.) correspond to a hologram. Each hologram of an area Hᵢ is associated with a respective reference m1, m2, m3, m4 which is formed with the hologram, and the position of that reference is characteristic of that of the hologram. For reasons of production of the metallic strip bm, the positioning of the holograms cannot be guaranteed with sufficient accuracy, such that the spaces Li between the adjacent references mi, the positions of which are strictly characteristic of the position of the holograms, may vary slightly.

On rotary presses for adding patterns onto a substrate in strip form, such as that used for implementation of the method according to the invention, there is an area zi which is not accessible for measuring the position on the supply strip bm. Consequently, it is not possible to place a detector for the references mi in the immediate vicinity of the block-holder roller 1, which would obviously be desirable. This is why a detector t is disposed upstream from the rollers 1, 2.

Since it is preferable to read the references mi when the supply strip is being displaced at constant speed, the detector t is therefore preferably disposed at a distance from a reference plane which passes through the two axes of rotation of the two rollers 1, 2. It is in this reference plane that the patterns are transferred by the blocks hᵢ, fᵢ, gᵢ from the supply strip bm to the substrate in strip form c. The distance between this reference plane which contains the axis of the rollers 1, 2 and the detector t corresponds to n times L, wherein L corresponds to a mean of the Li variables, such that the reading corresponds to a period during which the supply strip is displaced at constant speed, since it must accompany the block-holder roller 1 during the operation of transfer of the patterns to the substrate in strip form c, this roller 1 rotating at constant speed. In the formula n×L in the example illustrated, n is equal to 3 and this gives the distance which separates the reference plane from the detector t.

In order to economize on the material of the supply strip bm, the distance which separates the specific adjacent areas Hᵢ, Fᵢ, Gᵢ on this supply strip bm is obviously reduced, but that distance does not correspond to that distance which will separate the patterns which are cut from these respective specific areas when they are deposited on the substrate c. The difference between the distance between two adjacent patterns on the supply strip bm and the distance between these same two patterns on the substrate in strip form c constitutes a constant basic parameter, which is integrated in the control processor in order to process the speed profile of the supply strip bm.

Once the angular positioning of the block-holder roller 1 has been carried out relative to printing references (not shown) which are present on the substrate in strip form c, the method for positioning according to the present invention is implemented as follows:

The reading by the detector t of the reference m1 on the supply strip bm is triggered in predetermined angular position of the roller which correspond to the alignment of the blocks h1, h2, h3 with the plane which joins the axes of the two rollers 1, 2 and which corresponds to the position of transfer of the holograms in areas H1, H2, H3 from the supply strip bm to the substrate in strip form c, at which moment the supply strip bm is displaced at a constant speed.

The detector t measures the difference e1 which exists at this precise moment between a reference position in which the reference m1 should be located, and the real position of the latter. Let this difference e1=−0.2 mm. The correction of k1 to be carried out is therefore k1=−e1, therefore k1=+0.2 mm.

The position of the next block h2 calculated by the plane which joins the two axes of the rollers 1, 2 triggers reading by the detector t of the reference m2 which is characteristic of the position of the hologram H2. If the difference measured is for example e2=+0.1 mm, there is storage of the new modified correction for the position of the hologram Hᵢ, i.e. k11=−e1−e2, therefore k11=+0.1 mm.

There is also storage of a first correction for the position of the hologram H2, i.e. k2=−e2, therefore k2=−0.1 mm.

The position of the block h3 calculated by the plane which joins the two axes of the rollers 1, 2 triggers reading of the characteristic reference m3 of the position of the hologram H3. If a difference of e3=−0.4 mm is found for example, there is storage of a new modified correction for the position of H1, i.e. k111=−e1−e2−e3, in this case k111=+0.5 mm. There is storage of a modified correction for the position of H2, i.e. k22=−e2−e3, in this case k22=+0.3 mm, and there is also storage of a first correction for the position of the hologram H3, i.e. k3=−e3, in this case k3=+0.4 mm.

The correction k111 is used to determine the speed profile of the supply strip bm, such that H1 coincides exactly with the angular position of the block h1 on the roller 1.

At the precise moment when the calculation determines that the block is aligned on the plane which connects the two respective axes of the rollers 1, 2, reading of the reference m4 which is characteristic of the position of the hologram H4 is triggered. A difference e4 is measured, for example e4=−0.3 mm. The correction k1 is then erased from the memory, which retains only the data relating to the references mi which are situated between the detector t and the plane which contains the axes of the two rollers 1, 2.

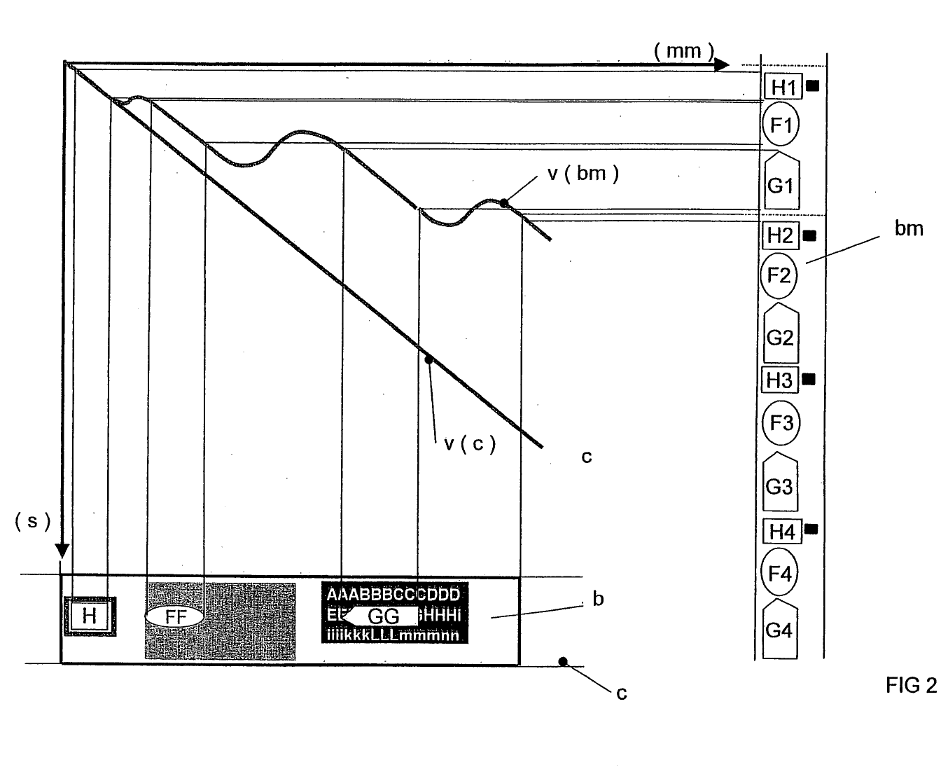

The diagram in FIG. 2 illustrates the respective profiles of the displacements (mm) of the substrate strip c and of the metallized supply strip bm, on a time basis (s). Parallel to the x-axis, there is also representation of the substrate strip c with the patterns deposited, and parallel to the y-axis there is representation of the supply strip bm with its specific areas for depositing of the different patterns.

It can be observed that the respective speeds of the strips V(c) and V(bm) are the same during depositing of the patterns of the supply strip bm onto the substrate strip c, the respective displacement profiles of these strips c and bm being parallel. The substrate strip c is displaced at constant speed, such that its speed profile is a straight line. When the two strips c, bm are displaced at the same speed, their profiles are parallel. Between the operations of depositing of two successive patterns, the speed profile of the supply strip bm is adapted according to the displacement which the substrate in strip form c must undergo at constant speed, as far as the location onto which the next pattern must be deposited, and according to the far shorter displacement which the supply strip bm must undergo in order to move from one specific area to the next.

As previously stated, the precision required for the positioning of these different areas is not very great. On the other hand, the precision required is great for positioning of the holograms Hi. In this case, the speed profile is determined by using the correction mode previously described, between the detector t and transfer of the hologram. It should be noted that the number n of lines of the memory can vary according to the work and the number of patterns in each group of patterns.

The processor used to carry out the command of the speed profile of the device for entrainment of the supply strip bm is programmed according to the mean parameters relating to the lengths Li between the successive groups of specific areas Hᵢ, Fᵢ, Gᵢ, the constant speed of the substrate in strip form c, and the differences in lengths between the distances which separate the successive patterns on the supply strip bm, and those which separate these same successive patterns on the substrate in strip form c. At each measurement of a difference between the position of a reference mi measured at the calculated passage of the blocks hi on the plane which joins the axes of the rollers 1, 2 and a reference position for this same reference, there is added to these parameters the correction to be made in order to take this difference into account, and which corresponds to the inverse of this difference. All the differences of the references which are situated between the detection position and the position of transfer of the holograms Hᵢ onto the substrate are added such that the correction made on the hologram Hᵢ which is reaching the transfer position occupies a position which corresponds accurately to the block hi of the roller 1 of the rotary press, when the latter coincides with the precise location of the imprint borne by the substrate in strip form c.

By this means, at each transfer of a hologram Hi onto the substrate in strip form c, correction of the position of the strip bm is superimposed on the standard speed profile of the control processor of the entrainment device, so that the hologram Hi borne by the supply strip bm coincides accurately with the block hi of the roller 1.

Although the present invention has been described in relation to a particular embodiment thereof, many other variations and modifications and other uses will become apparent to those skilled in the art. It is preferred, therefore, that the present invention be limited not by the specific disclosure herein, but only by the appended claims.

1. A method for positioning and transferring at least two series of patterns, wherein each series is comprised of respective different patterns, the method comprising:
entraining a substrate in strip form, which substrate receives transferred patterns, to move at a constant speed;
providing a supply strip on which there is a succession of pattern groups, with each group formed by at least two specific areas, and each area is for one of the patterns and the groups having respective homologous references in the respective areas thereof;
entraining the supply strip to move at the constant speed during a transfer of the patterns from the supply strip to the substrate, and providing the supply strip with a speed profile that is determined between two transfers of the patterns; determining the speed profile by measuring the time elapsed between two homologous references of the at least two specific areas of two successive ones of groups; determining from the measured time, the times when the entrained supply strip is to be displaced during the transfers of the two patterns; calculating the length between the respective adjacent patterns on the supply strip and comparing the calculated length with the length of the displacement between the respective locations of the same two consecutive patterns on the substrate for making the transfer of the patterns from the supply strip to the substrate coincide with respective selected locations for the patterns on the substrate.

2. The method according to claim 1, wherein the substrate is in strip form and is provided with imprints to which the patterns are to be respectively positioned, the method comprising positioning the successive patterns on the substrate relative to the previously provided imprints on the substrate.

3. The method according to claim 1, further comprising providing a hologram on at least one of the specific areas of each of the groups on the supply strip.

4. The method according to claim 3, wherein at selected times and at a selected distance from a reference point, detecting the difference between the position of each of successive references, each reference being a characteristic of a position of a respective hologram on the supply strip, and also detecting the respective selected distance;
based on the detection, determining a specific speed profile for a displacement of each hologram along the respective selected distance, the determination comprising measuring the difference between each of the respective references, generating a correction of the difference and obtaining a sum of the corrections of all of the references located between the point of detection and the reference point.

5. The method according to claim 4, wherein the given distance corresponds to n times the length of a group of specific areas located upstream from the reference point.

6. The method according to claim 4, wherein the length of each of the areas is determined in accordance with the length of the longest required pattern.

7. The method according to claim 1, wherein the length of each of the areas is determined in accordance with the length of the longest required pattern.
